(19) United States
(12) Patent Application Publication
(10) Pub. No.: US 2008/0048669 A1
(43) Pub. Date: Feb. 28, 2008

(54) Topological mapping using a conductive infrastructure

(76) Inventors: Dzulkifli Saul Scherber, North Potomac, MD (US); Jay Joseph Pulli, Fairfax, VA (US); Ernest Scott Stickles, Lothian, MD (US); Michael Steele, Herndon, VA (US); Carole Steele, Herndon, VA (US); Zachary Michael Upton, Silver Spring, MD (US)

Correspondence Address: PROSKAUER ROSE LLP, ONE INTERNATIONAL PLACE, BOSTON, MA, 02110, US

(21) Appl. No.: 11/511,077

(22) Filed: Aug. 28, 2006

(51) Int. Cl. G01R 31/11

(52) U.S. Cl. 324/534

(57) ABSTRACT

Described are methods and apparatus, including computer program products, for topological mapping using a conductive infrastructure. A conductive infrastructure of a structure is excited with an excitation signal. The radiated signal is received, the radiated signal being based on the excitation signal and an impedance discontinuity within the conductive infrastructure. A location associated with the impedance discontinuity is determined based on the received radiated signal.

### FIELD OF THE INVENTION

The present invention relates to topological mapping using a conductive infrastructure.

### BACKGROUND

A variety of technologies have been developed that use signal processing to remotely interrogate the interior of objects, both large and small. For example, technology has been developed to attempt to map the earth's subsurface for oil and gas exploration (see e.g., “Inversion of Geophysical Data”, L. R. Lines (ed), Society of Exploration Geophysicists Reprint Series No. 9, 1988, p. 543). In the exploration problem, a seismic source is initiated at the earth's surface, or down a borehole, and the resulting seismic energy propagates into the subsurface where it is reflected and refracted by geologic boundaries. In terms of wave propagation, these boundaries serve to bend the seismic energy back toward the surface, where seismic sensors record the energy. The arrival times and amplitudes of the seismic energy at these sensors are then used to invert for the unknown subsurface structure. Often, this is accomplished using some a-priori knowledge of the subsurface velocity structure, which can be measured along a one-dimensional borehole using downhole tools. An iterative procedure is set up whereby this initial model is used to compute synthetic travel times to the receivers, which are then compared with the data, then the model is modified and times are recalculated.

In another example, commercially available Time Domain Reflectometry (TDR) technology consists of propagating an energy pulse through a cable and observing the pulse reflections within the same cable to detect, characterize and estimate the locations of disconnects within the cable (see e.g., “TDR Tutorial and Riser Bond TDR Product Review”, http://www.ostgate.com/riserbond.html). This technology can be applied to both optical cables and electrical cables. In the case of electrical cables, there must be at least two conducting wires that act as a transmission line for the inserted pulse. Typical TDR technology detects and locates disconnects that often occur when a cable is damaged. The time of arrival of the reflection from such a disconnect along with a known propagation velocity along the cable indicates the cable distance to the damage.

In another example, multi-static radar is composed of multiple radiation transmitters and multiple radiation receivers in a variety of special configurations. Multi-static radar is similar to mono-static radar (a single, collocated transmitter/receiver pair) and bi-static radar (a single, spatially separated transmitter/receiver pair) in that signal energy illuminates a target by propagating for a distance from a transmitter to the target. Signal energy then propagates back from the target to the receivers where it is observed. Observations of arrival times of the received signal energy can be processed for detection, localization and tracking purposes. Multi-static radar has advantages over mono-static and bi-static radar in that it provides a variety of paths by way of the target over which to observe propagating signals, each with its advantages and disadvantages. Processing over the set of observation paths potentially provides more information about the target than could be obtained with a single mono-static or bi-static radar system. For example, Larry Fullerton and Time Domain Corporation have developed commercial mono-static Ultra-Wideband (UWB) radar products, which propagate signals through free space and various building materials (see e.g., “RadarVision”, Time Domain Corporation, http://www.radarvision.com). Larry Fullerton and James Richard have also patented a system and method using multi-static UWB radar for intrusion detection which consists of multiple designed transceivers placed on the periphery of a structure to detect, locate and track motion within a structure (see U.S. Pat. No. 6,710,736, titled “System And Method For Intrusion Detection Using A Time Domain Radar Array”).

### SUMMARY OF THE INVENTION

This section describes methods and apparatus, including computer program products, for topological mapping using conductive infrastructure. For example, topological mapping of a building interior can be obtained using its conductive infrastructure, such as its electrical wiring. For example, an impulsive electrical signal is inserted onto the conductive infrastructure. This signal propagates along the wires and when it encounters an impedance discontinuity, it radiates into free space. This signal is then received directly on other impedance discontinuities, or may be reflected from an interior object and then be received on an impedance discontinuity. In one aspect, there is a method for topological mapping. A conductive infrastructure of a structure is excited with an excitation signal. The radiated signal is received, the radiated signal being based on the excitation signal and an impedance discontinuity within the conductive infrastructure. A location associated with the impedance discontinuity is determined based on the received radiated signal.

In another aspect, there is a system that includes a signal generator and a signal processor. The signal generator is adapted to excite at least a portion of a conductive infrastructure of a structure (e.g., a building) with an excitation signal. The signal processor is adapted to receive a radiated signal and a reflected signal. The radiated and the reflected signals are based on the excitation signal and an impedance discontinuity within the conductive infrastructure. The signal processor is further adapted to determine a location associated with the impedance discontinuity based on the received radiated and reflected signals.

In another aspect, a computer program product may be tangibly embodied in an information carrier, for topological mapping using conductive infrastructure. The computer program product includes instructions being operable to cause data processing apparatus to excite at least a portion of a conductive infrastructure of a structure with an excitation signal and receive a radiated signal and a reflected signal, the radiated and the reflected signals being based on the excitation signal and an impedance discontinuity within the conductive infrastructure. The computer program product also includes instructions being operable to cause data processing apparatus to determine a location associated with the impedance discontinuity based on the received radiated and reflected signals.

Any of the aspects may include one or more of the following features. The radiated signal can be received by the conductive infrastructure, the impedance discontinuity within the conductive infrastructure, and/or an antenna. The radiated signal can be received after the radiated signal has been reflected off an element of a non-electrical infrastructure. The radiated signal can be received using a first conductor of the conductive infrastructure that is electrically insulated from a second conductor of the conductive infrastructure through which the excitation signal is carried.

A reflected signal can also be received. The reflected signal can be based on the excitation signal and the impedance discontinuity within the conductive infrastructure. The location associated with the impedance discontinuity can be determined based on the received radiated signal and the received reflected signal. The reflected signal can be received using the conductive infrastructure. In some examples, the reflected signal is not based on a radiated signal received by the impedance discontinuity. The reflected signal can be based on a radiated signal received by the impedance discontinuity, multiple reflections in free space, a radiated signal received by the impedance discontinuity that is generated by a different impedance discontinuity, and/or a radiated signal received using a first conductor of the conductive infrastructure that is electrically insulated from a second conductor of the conductive infrastructure through which the excitation signal is carried.

The excitation signal can be transmitted using a connection to the conductive infrastructure. The connection can be matched with an impedance value associated with the conductive infrastructure. The connection can include a circuit breaker box, a transformer, an outlet, or any combination thereof. The excitation signal can be transmitted using an antenna.

The location can be determined by comparing the received reflected and radiated signals to a model. The determining can include iteratively changing a parameter of the model. The model may include propagation velocities, radiation efficiencies, refractions, attenuation parameters, or any combination thereof. The location can be determined when the received reflected and radiated signals match the model. A match can be determined by determining to a probabilistically high confidence level that there is a match.

The received and reflected signals can be based on a plurality of impedance discontinuities. The locations associated with the plurality of impedance discontinuities can be determined using the received and reflected signals. The layout of the structure may be based on the determined locations. At least a portion of the layout of the structure can be displayed. Coordinates of the locations can be determined. A probability corresponding to each of the locations can be determined.

The conductive infrastructure can include electrical power wiring, at least two conductors, and/or non-metallic sheathed cable. The excitation signal can include a radar signal and/or a broadband signal. The location can include a geographical location, spatial location and/or a multi-dimensional location.

Implementations can realize one or more of the following advantages. Because some propagation paths include propagation along some part of a structure's electrical network, there is potentially less signal energy loss by propagating through the electrical network than through free space that may include attenuating walls. Also, implementations are not limited to a particular type of radar signaling. The described techniques enable mapping of a previously unknown structure, an ability that is desired in a number of situations ranging from assessing recently vacated property to assessing a structure involved in a hostage situation. The techniques deal with two propagation velocities: the free-space electromagnetic propagation at the speed of light, and the speed of electromagnetic pulse propagation down wires within the electrical network performing as a transmission line. Because there will be no significant refraction, or bending of the ray paths, the iterative process to determine location can be a linear iterative process. The techniques can use observations of radiated energy from discontinuities in the electrical network as well as internal reflections. The techniques enable the generation of a map of an electrical network which includes a larger number discontinuities.

There are several advantageous uses for the described technology. Urban military forces can use the technology for remotely evaluating the electrical network and potential interior structure of a target building before future navigation. Federal, State and local Government Police, Firefighters and Emergency Responder/Rescue personnel can use the technology to remotely evaluate the electrical network and interior structure of a building in its current state for real-time emergency response planning. Absentee landlords/private security agencies can use the technology to maintain economical persistent monitoring of a building's electrical network and internal structures associated with the electrical network. One implementation of the invention may provide all of the above features and/or advantages.

The details of one or more examples are set forth in the accompanying drawings and the description below. Further features, aspects, and advantages of the invention will become apparent from the description, the drawings, and the claims.

### BRIEF DESCRIPTION OF THE DRAWINGS

FIG. 1 illustrates an exemplary signal flow diagram for topological mapping using a conductive infrastructure.

FIG. 2 illustrates a block diagram of some exemplary signal reactions when a propagated signal, traveling through a conductive infrastructure, encounters an impedance discontinuity.

FIG. 3 illustrates a block diagram of some exemplary signal reactions when the impedance discontinuity receives a radiated signal.

FIG. 4 illustrates a block diagram of an exemplary system for topological mapping using a conductive infrastructure.

FIG. 5 illustrates a block diagram of an exemplary system in which a propagated signal is reflected from an impedance discontinuity.

FIG. 6 illustrates a block diagram of an exemplary system in which a propagated signal is radiated from an impedance discontinuity and received by another impedance discontinuity.

FIG. 7 illustrates a block diagram of an exemplary system in which an observation interface observes signals using an external antenna network.

### DETAILED DESCRIPTION

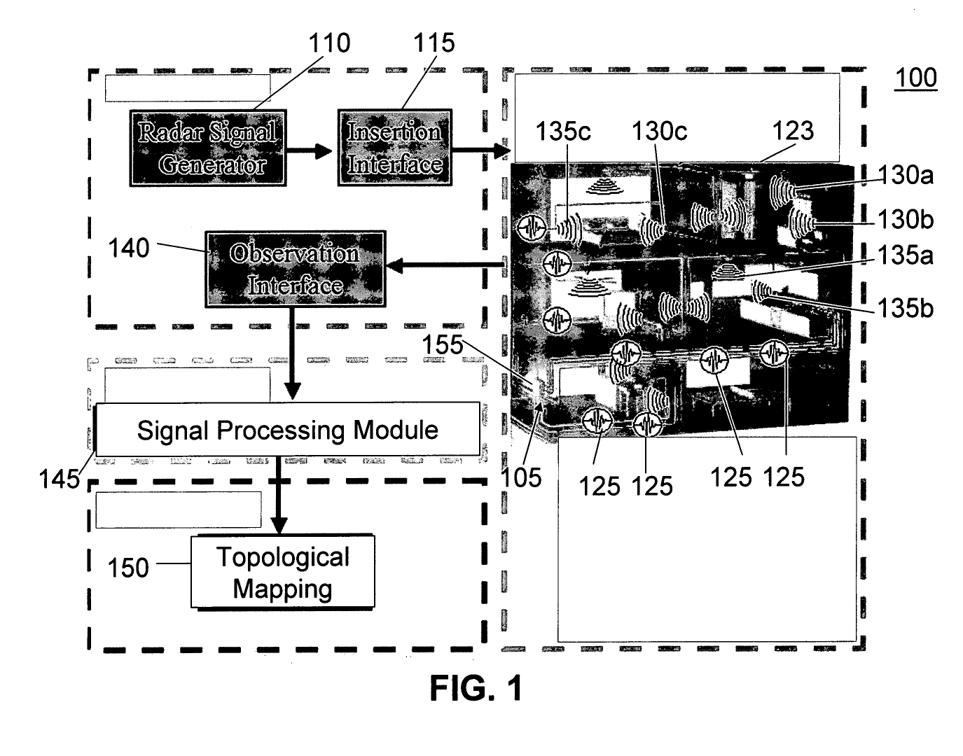

FIG. 1 illustrates an exemplary signal flow diagram 100 for topological mapping using a conductive infrastructure 105 (e.g., a structure's electrical network and other internal structural features). The technique for generating a topological mapping of a structure's electrical network and other internal structural features is sometimes referred to herein as power line radar for topological mapping (“PLR-TM”). As described in more detail below, PLR-TM is a technique that includes processing a complex set of reflected, radiated, and response signals involving the excitation of the structure's conductive infrastructure 105 with excitation signals, such as radar signals.

In the signal flow diagram 100, there is a radar signal generator 110 that generates a continuous signal and/or a sequence of pulses, each of which contain energy over a desired frequency spectrum. The signal generator 110 communicates the signal to an insertion interface 115. The insertion interface 115 includes an interface to communicate the signal to the conductive infrastructure 105 of a structure 123. The signal propagates through the conductive infrastructure 105, as represented by elements 125 in the flow diagram 100.

The conductive infrastructure 105 includes different types of impedance discontinuities, for example a light fixture 130a, a light switch 130b, an electrical outlet 130c, and the like, represented generally as an impedance discontinuity 130. When the propagated signal encounters an impedance discontinuity 130, the signal can react in many different ways. For example, the signal can be reflected back through the same conductive infrastructure element (e.g., a wire) through which the signal was originally propagated. In another example, the signal can be radiated. For example, a signal 135a is radiated from a light fixture, a signal 135b is radiated from another light fixture, a signal 135c is radiated from an electrical outlet, and other signals (not referenced) are radiated from other impedance discontinuities distributed throughout the conductive infrastructure 105.

The flow diagram 100 includes an observation interface 140, which is an interface that receives signals from the conductive infrastructure 105 that are reflected back, radiated back, or some combination of being radiated and reflected, sometimes being radiated and/or reflected multiple times. The flow diagram 100 includes a PLR signal processing module 145 in communication with the observation interface 140. The signal processing module 145 process the received signals from the observation interface 140 and produces a topological mapping 150 of the conductive infrastructure 105 and/or the structure 123 based on the received signals.

An exemplary PLR-TM technique described using the flow diagram 100 addresses the challenge of mapping (e.g., identifying the locations of multiple features within) an unknown structure, such as the multi-story structure 123, while under the constraint of limited access to the interior of the structure 123. In this example, numerous pulses of energy generated by the radar signal generator 110 excite the conductive infrastructure 105 from an access point outside the structure 123, such as a transformer connection to the external power grid. These pulses propagate through elements of the conductive infrastructure 105 causing reflected signals within the conductive infrastructure 105 and radiated signals throughout the structure 123. The conductive infrastructure 105, having a tree-like structure, also facilitates one branch receiving radiation from another branch. An antennae network (not shown) outside the structure 123 can observe radiated and reflected signals propagating through non-electrical infrastructure, such as air. Sensors at the access point (e.g., observation interface 140) can observe reflected and received signals propagating within the conductive infrastructure 105. The PLR signal processing module 145 inverts the observed signals arrival time and frequency structure set to construct a topological map of the conductive infrastructure 105. Frequency structure can refer to, for example, frequency dependent filtering that can be part of identifying and localizing topological features. A topological map of the conductive infrastructure 105 implies wall locations, which can contain the electrical infrastructure and appliance locations which connect to the electrical infrastructure receptacles, suggesting the internal layout of the structure 123. Variations in other examples can include exciting the conductive infrastructure 105 from the network of external antennae (not shown), exciting portions of the conductive infrastructure 105 from within the structure 123, or using various combinations of systems to observe the reflected and radiated signals.

In more detail, the conductive infrastructure 105 can include an electrical network, which can include, for example, cabling, junctions, receptacles and appliances. Examples of cabling include main power feeder cable and Romex® cable. Main power feeder cable can include two or three high gauge conducting wires and an additional ground conducting wire. Romex® cabling includes two conductors of lesser gauge than the main feeder cable and an additional ground wire conductor. The preferred characteristic for cabling in some examples is that each length of cable includes at least two conductors of similar dimension to form a lossy transmission line along which the balanced energy pulse can propagate. The energy loss and propagation velocity of pulses vary with cable structure, style and quality of materials. The conductive infrastructure 105 can also include junctions, such as breaker boxes (e.g., 155), light switch boxes (e.g., 130b) and electrical power splitters. The conductive infrastructure 105 can also include electrical receptacles, such as outlet boxes (e.g., 130c) and light sockets (e.g., 130a). The conductive infrastructure 105 can also include appliances, such as light fixtures, light bulbs, fans, electrical heaters, computing equipment, and other machinery that requires electrical power from the electrical network.

Each of the described exemplary features of an electrical network has characteristic impedance. For example, in cabling acting as a transmission line, the characteristic impedance depends on the orientation of the two conductors. A junction box alters the orientation of the two conductors and causes an impedance discontinuity. Similar discontinuities occur at the connection between the transmission line conductors and a differently structured cable. An example is the connection between an electrical outlet and an appliance power cord. Throughout the conductive infrastructure 105, several different impedance discontinuities exist and cause signal reactions to the propagated signal.

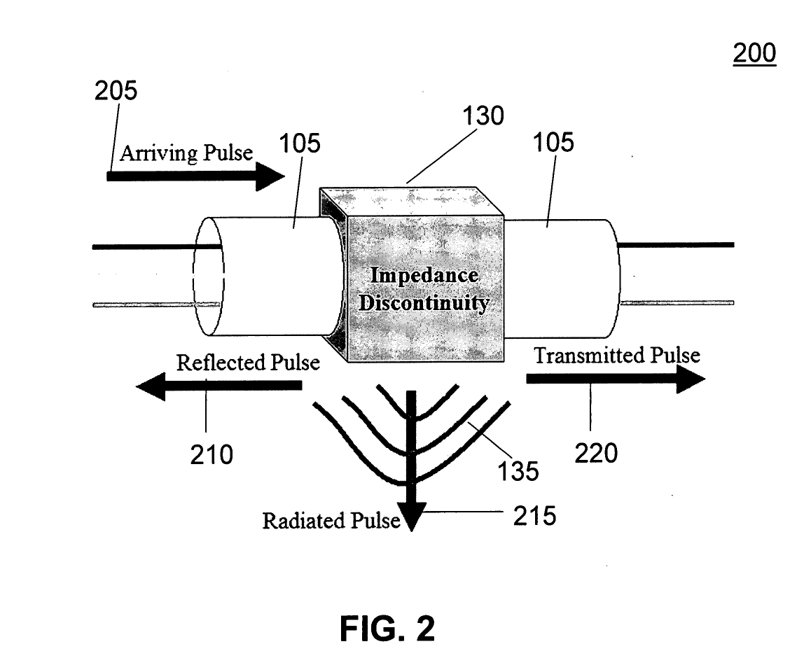

FIG. 2 illustrates a block diagram 200 of some exemplary signal reactions when a signal, propagates within the conductive infrastructure 105 (e.g. an electrical cable with several conducting wires) in the direction of arrow 205, and encounters the impedance discontinuity 130. The impedance discontinuity 130 can divide a propagating energy pulse into reflected energy pulse, represented by an arrow 210, a radiated energy pulse 135, represented by an arrow 215, a transmitted energy pulse, represented by an arrow 215, and/or thermal loss (not shown). The reflected energy 210 propagates through the conductive infrastructure 105 in the opposite direction of the arriving pulse 205. The transmitted energy 220 continues along the conductive infrastructure 105 in the original direction of propagation (if a transmission line of the conductive infrastructure 105 continues past the impedance discontinuity 130). The radiated energy 215 enters free space, is no longer guided by the transmission line properties of the conductive infrastructure, and may propagate in all directions from the impedance discontinuity 130. Generally, the radiated impulse energy 215 travels through free space with an attenuation of the inverse of the distance traveled. Directionality and polarization of the radiated energy pulse 215 depends on characteristics and orientation of the impedance discontinuity 130. In general, thermal energy is not significant and the environment absorbs it as heat. The relationships between the resultant energies depend on the severity and structure of the impedance discontinuity 130 and the frequency and energy levels of the arriving pulse 205. For example, the impedance discontinuity is characterized by the spatial relationship between the two conductors. The spatial configuration of these two conductors varies widely based on the available materials as well as skill and style of the person installing or modifying the conductor to electrical infrastructure. An electrical junction box is an exemplarily impedance discontinuity that involves conductors of various length, connected together to support the electrical power circuits. Once the necessary connections are made, the lengths of conductor are twisted such that they fit within the junction box. The twisting of the conductors determines their spatial relationship and, in turn, the characteristic of the impedance discontinuity.

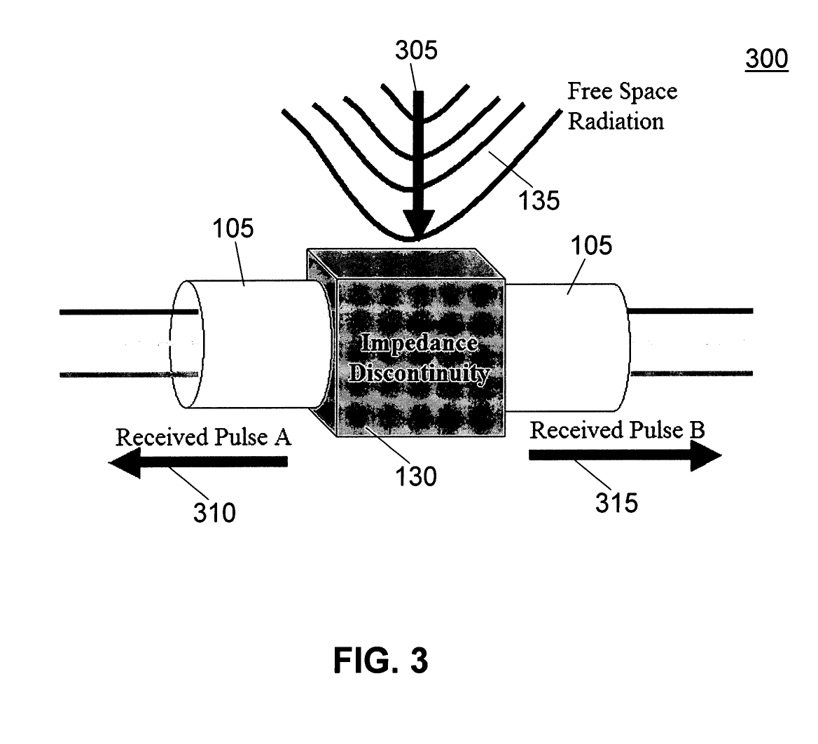

FIG. 2 illustrates an example where the impedance discontinuity 130 receives the arriving signal 205 through a wire pair of the conductive infrastructure 105. The impedance discontinuity 130 can also receive signals in other ways. FIG. 3, for example, illustrates a block diagram 300 of some exemplary signal reactions when the impedance discontinuity 130 receives a radiated signal (e.g., a radiated signal 135 from another impedance discontinuity), represented by arrow 305. In this example, the impedance discontinuity 130 converts the radiated energy signal 305 from free space to energy pulses that propagate along a transmission line (e.g., a wire) through the conductive infrastructure 105.

In FIG. 3, the impedance discontinuity is connected to the conductive infrastructure on two sides. In this example, the impedance discontinuity 130 converts the radiated energy signal 305 from free space to an energy pulse A, within the conducting infrastructure in the direction of arrow 310, that travels through the conductive infrastructure 105 in a direction away from the impedance discontinuity 130 on one connected side and an energy pulse B, along the wire pair in the direction of arrow 315, that travels through the conductive infrastructure 105 in a direction away from the impedance discontinuity 130 on the other connected side. The efficiency of receiving the radiated energy 305 depends on the nature of the impedance discontinuity 130. The relationships between the various received pulses 310 and 315 propagating along the conductive infrastructure 105 associated with the impedance discontinuity 130 also depend on the impedance discontinuity's electrical nature (e.g., whether the impedance discontinuity 130 is a partial open, a partial short, etc.).

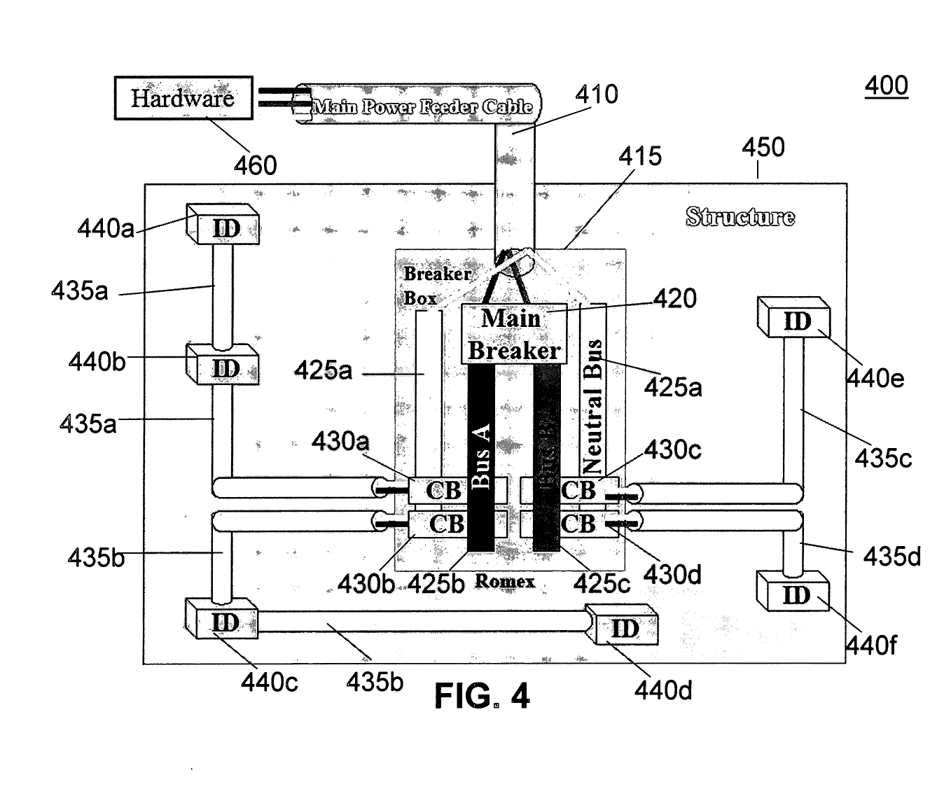

The configurations of the cabling and impedance discontinuities components vary widely between individual structures. FIG. 4 illustrates a block diagram of an exemplary system 400 for topological mapping using a conductive infrastructure. The conductive infrastructure includes a main feeder cable 410, and a main breaker box 415 that includes a main breaker 420, bus bars 425a, 425b, 425c, and 425d, and circuit breakers 430a, 430b, 430c, and 430d. The conductive infrastructure 405 also includes insulated electrical wiring 435a, 435b, 435c, and 435d, and impedance discontinuities 440a, 440b, 440c, 440d, 440e, and 440f.

The main feeder cable 410 enters a structure 450 from outside and supplies power through the main breaker 420 at the main breaker box 415. The bus bars 425a-d and circuit breakers 430a-d divide the input power into multiple circuits. In the United States, the main breaker box 415 often includes two hot busses, 425b and 425c, one associated with each of the hot conductors of the feeder cable 410. Both busses 425b and 425c use the same neutral conductor 425a to complete any electrical circuit within the structure 450. Each circuit breaker (e.g., 430a and 430b) connects the hot conductor of the electrical wire (e.g., 435a) to the hot bus (e.g., 425b), and the neutral conductor of the electrical wire (e.g., 435a) to the neutral return bus (e.g., 425a). The electrical wire (e.g., 435a) also connects to other junctions (e.g., 440a) and receptacles (e.g., 440b) on a particular circuit.

The system 400 includes hardware 460 that is connected to the main power feeder cable 410 external to the structure 450. The hardware 460 transmits an excitation signal through the conductive infrastructure via its connection to the main power feeder cable 410 and receives a radiated and/or reflected signal also via its connection to the main power feeder cable 410. Based on those received signals and other side information, the hardware 460 determines the probable locations of each of the impedance discontinuities 440a-f. Based on the locations of each of the impedance discontinuities 440a-f, the hardware 460 can estimate the layout (e.g., locations of walls, ceilings, floors, doorways, etc.) of the structure 450. In some examples, the hardware 460 displays the estimated locations of each of the impedance discontinuities 440a-f and/or the estimated layout of the structure 450. The sophistication of the display can vary, for example, from a simple displaying of coordinates of locations to a three-dimensional plotting of locations to a simulated three-dimensional drawing of the structure (e.g., as represented by structure 123 in FIG. 1).

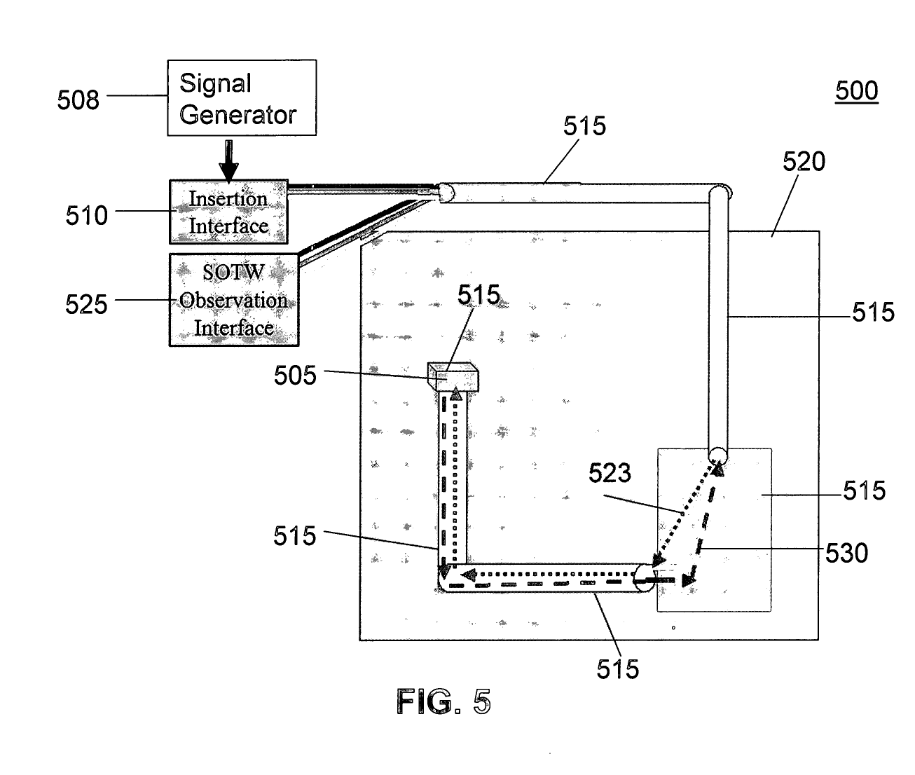

FIG. 5 illustrates a block diagram of an exemplary system 500 in which a propagated signal is reflected within the electrical infrastructure from an impedance discontinuity 505. A signal generator 508 generates a signal and communicates that signal to an insertion interface 510. A function of the insertion interface 510 is to insert a generated signal (e.g., a radar signal) into an electrical network 515 running throughout a structure 520, using, for example, a pair of conducting wires connected to the electrical network 515. In some examples, the insertion interface 510 matches the impedance of the electrical network 515 and minimizes radiation from the interface 510 between the signal generator 508 and the electrical network 515. For example, the insertion interface 510 can match impedances between microwave rated coaxial cable, with characteristic impedance of 50 Ohms, and typical Romex® cable found within the United States, with characteristic impedance near 120 Ohms. The invention is not limited to these specific impedance relationships. The insertion interface 510 can involve a pair of conducting wires that act as a transmission line within the structure's electrical network 515. Although one connection is shown, in other examples, the signal generator 508, or a set of signal generators, with or without the insertion interface 510, can connect to a number of locations connected to a structure's electrical network including, outside and within the structure.

The signal travels through the conductive infrastructure 515 towards the impedance discontinuity 505, as represented by arrow 523. When the signal encounters the impedance discontinuity 505, the signal is reflected back towards an observation interface 525, as represented by the arrow 530. FIG. 5 refers to the observation interface 525 as the sense-on-the-wire (SOTW) observation interface 525. The sense-on-the-wire observation interface 525 is physically connected to the structure's electrical network 515 at an access point. The observation interface 525 directly observes signals propagating through the electrical network 515. In this example, these observed signals include reflections due to impedance discontinuities (e.g., 505) within the electrical network 515. Similar to the insertion interface 510, in some examples the impedance of the SOTW observation interface 525 matches the impedance of the electrical network access point so as to minimize reflections or radiation.

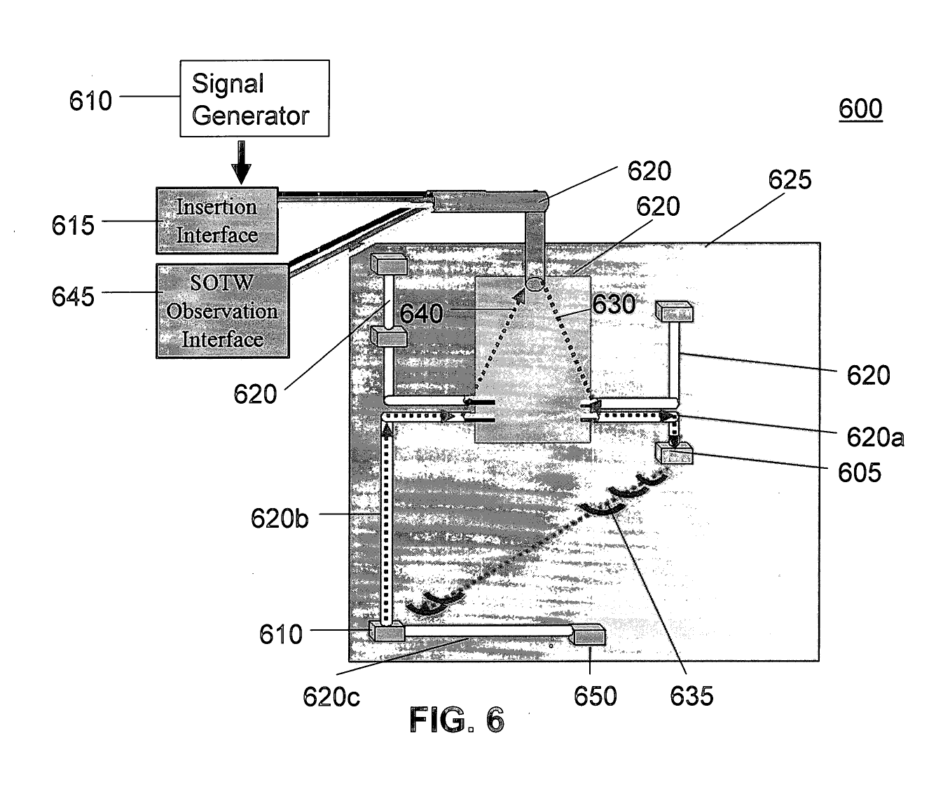

FIG. 6 illustrates a block diagram of an exemplary system 600 in which a propagated signal is radiated from an impedance discontinuity 605 and received by another impedance discontinuity 610. A signal generator 610 generates a signal and communicates that signal to an insertion interface 615. The insertion interface 615 inserts the generated signal (e.g., a broadband signal) into an electrical network 620 running throughout a structure 625, using, for example, a pair of conducting wires connected to the electrical network 620.

The signal travels through the conductive infrastructure 620 and through a particular branch 620a towards the impedance discontinuity 605, as represented by arrow 630. When the signal encounters the impedance discontinuity 605, the signal is radiated, as represented by the arrow 635. The radiated signal 635 is received by the impedance discontinuity 610 and a received signal is generated, as represented by arrow 640. The received signal propagates to a sense-on-the-wire (SOTW) observation interface 645, which is physically connected to the structure's electrical network 620 at an access point. The observation interface 645 directly observes signals propagating through the electrical network 620. In this example, these observed signals include free space radiation (e.g., 635) received through impedance discontinuities (e.g., 610).

For clarity, FIG. 6 illustrates the propagation path of one signal as that signal travels through the conductive infrastructure 620 (e.g., 630), is radiated into the air at one impedance discontinuity 605 (e.g., 635), and received by another impedance discontinuity 610 and transmitted through the conductive infrastructure 620 once again (e.g., 640). In other examples, there are many other signals propagating through the conductive infrastructure and the free space and are being reflected and/or radiated multiple times. For example, the signal 630 can also be reflected at impedance discontinuity 605, with the reflected signal propagating back to the observation interface 645. In another example, the radiated signal 635 can be received by the impedance discontinuity 650. The signal received by the impedance discontinuity 650 can propagate through the electrical infrastructure 620c to impedance discontinuity 610. In response to that signal propagated from the impedance discontinuity 650, the impedance discontinuity 610 can transmit a signal through further elements of the conductive infrastructure 620 and radiate a signal into free space. The signal radiated by the impedance discontinuity 610 can be received by impedance discontinuity 605. As can be seen by one skilled in the art, many more variations and combinations of signals being reflected and/or radiated than those explicitly described are possible and contemplated.

The resulting signals observed at the SOTW observation interface 645 depend on the configuration of cabling and impedance discontinuities included in the conductive infrastructure 620. Impedance discontinuities associated with a given circuit (e.g., 610 and 650 included in the circuit 620b) form a system of spatially separated sequential impulse radar receivers. A radiation source (e.g., can include a target response that generates the radiation as a response to receiving radiation) may excite a received pulse at several impedance discontinuities, each of which propagate along the lossy transmission line to the SOTW observation interface 645. The path distance between the radiation source to the SOTW observation interface 645 is one of the factors that determine the times at which these received signals are observed. The path distance is composed of multiple legs through mixed mediums of free space and cabling, each of which has a propagation velocity and attenuation associated with it. The signal velocity and attenuation may also be dependent on power levels of specific signal frequency elements.

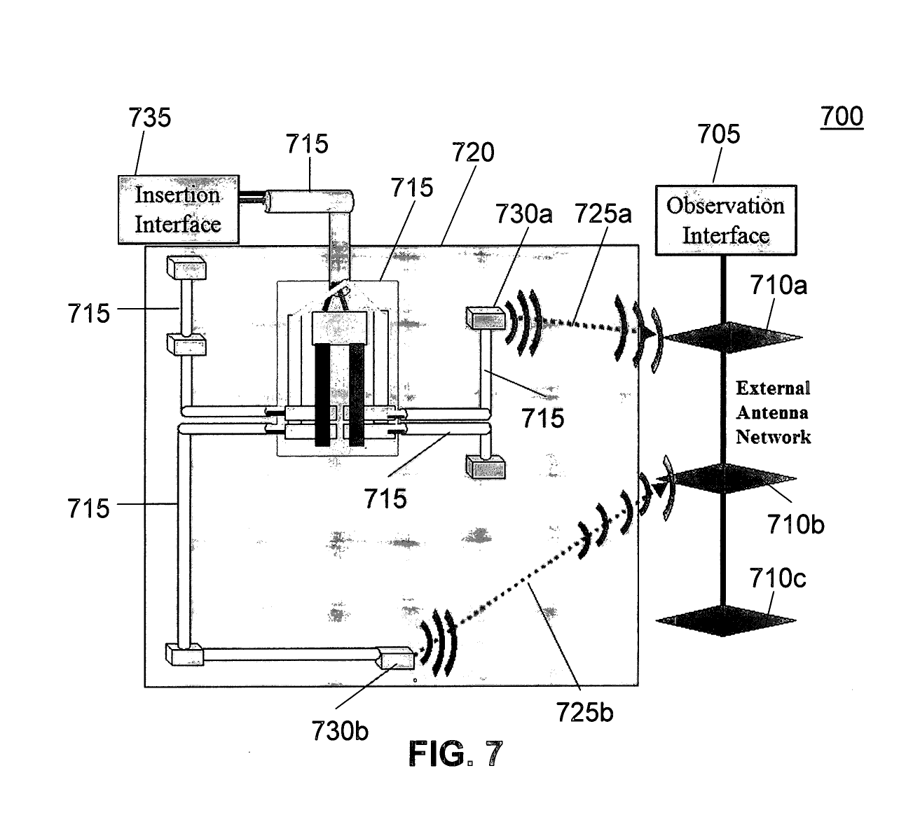

FIG. 7 illustrates a block diagram of an exemplary system 700 in which an observation interface 705 observes signals using an external antenna network 710, which includes antennae 710a, 710b, and 710c. The set of external antennae 710 are physically decoupled from a conductive infrastructure 715 of a structure 720 and may be outside or inside the structure 720. FIG. 7 illustrates an example where the external antennae 710 are located outside the structure. The invention is not limited to the linear configuration of external antenna illustrated in FIG. 7. The external antenna may be configured to take advantage of three dimensional special diversity as well as time and frequency diversity. Each antenna (e.g., 710a and 710b) collects radiation propagating through free space (e.g., radiated signals 725a and 725b). The radiation of interest is generated by impedance discontinuities (e.g., 730a and 730b) throughout the conductive infrastructure 715.

The external antennae 710 can also receive signals resulting from target response to the radiation sources, often referred to as indirect propagation paths. The external antennae 710 can receive both direct radiations from the impedance discontinuities (e.g., 730a and 730b) and responses of members of the non-electrical infrastructure in a bi-static radar mode. The multiple external antennae 710 can be used coherently to collect signals of unique sets of direct and indirect propagation paths. The time of arrival at the external antenna (e.g., 710a) depends on different factors. For example, one factor can be the propagation path length from an insertion interface (e.g., 735) to a radiating impedance discontinuity (e.g., 730a) through the conductive infrastructure 715. Another factor can be the free space path from the radiating impedance discontinuity (e.g., 730a) to the external antenna (e.g., 710a), either through a direct path, or an indirect path involving an element of a non-electrical infrastructure. It is possible to receive multiple, time-separated target responses associated with a single target when separate radiators illuminate the target at distinctly separate times. Various external antennae designs include characteristic directionality, frequency ranges of focus, amplifiers, and covert, mobile or dynamic designs.

In other alternative examples (not shown), an external antenna network can be used to excite the conductive infrastructure 715. In these examples, the observation interface can be connected to the infrastructure 715 (e.g., such as is shown in FIGS. 5 and 6).

Referring to FIG. 1, the signals that the observation interface 140 observes are processed by the signal processing module 145. Signals recorded through the observation interface 140 include several forms of information about the conductive infrastructure 105 of the structure 123 and other features internal to the structure 123. The observed signal is a combination of received signals. Each received signal at the observation interface 140 has propagated from the insertion point 115, through a path, which includes various segments of cabling and free-space, each with their own associated velocity and attenuation. The signal processing module 145 creates a topological map of the conductive infrastructure 105 through an iterative method of constructing electrical network models, predicting observations, and comparing prediction to actual observed signals. Each model consists of a possible electrical network, and interaction with members of the non-electrical infrastructure. The non-electrical infrastructure of a structure typically includes interior and external wall construction material, furniture, people and related mobile and non-mobile objects. The conductive infrastructure 105 of the structure 123 does not necessarily include everything conductive in the structure, although it can. In some examples, only those elements that are part of an electrical network (e.g., everything electrically connected to the circuit box 155) are considered part of the conductive infrastructure 105 that the processing module 145 attempts to model. In such examples, conductive elements that are not part of the electrical network are considered as part of the non-electrical infrastructure in the model. Free space within a structure is a general term to model, for example, all other contents (e.g., air) that do not fit into the above categories of an electrical network (conductive infrastructure) or non-electrical network. In some examples, and throughout this document, the terms free space and non-electrical infrastructure are used interchangeably and represent any elements that are not part of the active electrical network electrically connected to the excitation signal. Sets of propagation velocities, radiation efficiencies, and refractions can also be associated with each potential model.

The modeling works based on multiple radiating sources and receiving antennae generating an environment similar to that of a multi-static radar system. Generating a topological mapping of the electrical network is similar to localizing each multi-static source/receiver node and the path along a portion of the electrical network to each node from the reflections along the network path and observing external radiation patterns. The models used predict the model observed signals if the discontinuities are located at certain locations. Those locations are then changed iteratively based on differences between the actual observed signals and the predicted signals until there is a match, or at least a high probability that each of the impedance discontinuities is located within some small area.

For example, referring to FIG. 4, the set of impedance discontinuities associated with a given circuit form a multi-static radar environment. For example, in the circuit 435a, there are two impedance discontinuities 440a and 440b. Radar signals propagate along the Romex® cabling at a given velocity and arrive at each impedance discontinuity in sequential order as determined by the cable associated to the circuit layout. For example the signals traveling from the breaker box and traveling through circuit 435a, arrive at impedance discontinuity 440b first and then 440a second. The time between the arrival at 440b and 440a depends on the length of cable forming the propagation path from 440b to 440a and the propagation velocity along that path. The arrival at each impedance discontinuity radiates a signal into free space. Each radiated signal has a transmission path to the observation interface with at least one free space component which depends on relative locations of each impedance discontinuity and the observation interface. The observation interface (e.g., included in hardware 460) receives each of the radar signals in order of their arrival. The path distance from the insertion point to the observation interface, including both cable propagation and free-space propagation, along with associated propagation velocity and attenuation, determine the arrival order and signal strength at the receiver. A signal processing module models a circuit length and locations for each of the impedance discontinuities and iterates the lengths and locations until there is a high probability of a match.

Other examples can include variations as additions or alternatives to what has been described herein. For example, the signal insertion location can include various configurations coupling the conductive infrastructure and the insertion and observation interfaces. These configurations include but are not limited to coupling the additional hardware on the main power cable (two or more conductors) at some standoff from the structure, within or near any available electrical power meter on the exterior of the structure, within or near a breaker box panel within the structure, or through an electrical receptacle such as power outlet, light socket switch or junction box. Each interface represents a specific view of the transmission and reception channel and an associated surveillance scope and resolution within the structure. Each of these interfaces operates both while the conductive infrastructure is energized and de-energized.

In an exemplary main power cable from standoff configuration, the additional insertion and SOTW observation interface hardware can be connected to a structure's electrical power infrastructure at a standoff from the structure where the main power feeder for the structure connects through a transformer to the area power grid. Propagation time and signal attenuation can be taken into account along this main feeder cable. Selection of radiating particular areas of the structure by selecting circuits may be limited in this configuration if the circuit switches are not available.

In an exemplary structure exterior configuration, the additional hardware for pulse insertion and SOTW observation modes can be connected to the exterior of the facility at the point the main power feeder enters the structure. Propagation time and signal attenuation may be reduced by placing the insertion interface and observation interface at this point. Selection of radiating particular areas of the structure by selecting circuits may be limited in this configuration if the circuit switches are not available.

In an exemplary breaker box configuration, the additional hardware for pulse insertion and SOTW observation modes can be connected near or within the breaker box by either inserting pulsing and observation circuitry within a substitute main power breaker or substitute circuit breakers. Insertion through a substitute main power breaker eliminates insertion loss due to the main power feeder cable. Substitute circuit breaker insertion may either pulse to all circuits through the bus bars or de-couple a circuit from the bus bars and insert pulses on that circuit individually. A set of coordinated substitute circuit breakers advantageously offers flexibility to select to radiate and receive on any combination of circuits at the cost of de-coupling select circuits to isolate them.

In an exemplary electrical outlet configuration, additional hardware for pulse insertion and SOTW observation may be connected to an individual electrical outlet. The circuit attached to the insertion outlet connects all primary radiation sources. Some radiation sources may be on other circuits but will face additional delay, as the energy pulses must pass through the breaker box bus bar.

There can also be variations of the SOTW observation modes. For example, there can be two sense-on-the-wire (SOTW) observation modes, a pseudo-mono-static SOTW observation mode and a pseudo-bi-static SOTW observation mode. There can be configurations in which multiple observation modes may be used together to advantageously garner more information.

In an exemplary pseudo mono-static observation mode, the insertion interface and observation interface are combined into a single connection to two conductors. This observation mode can be available for all pulse insertion locations. Pulse energy is both inserted and received on these two conductors. In this example, the term pseudo-mono-static describes the collocation of transmit and receive interfaces. An electrical infrastructure with more than one impedance discontinuity produces both mono-static and bi-static mode observations. The mono-static mode observations arise when a single impedance discontinuity receives a signal that it originally sourced, such as a signal that is propagated through free space from the originating impedance discontinuity to another impedance discontinuity and then propagated back to the originating impedance discontinuity. The bi-static mode observations arise when a signal enters free space at a first impedance discontinuity and is received at a second spatially separated impedance discontinuity.

In an exemplary pseudo bi-static observation mode, the insertion interface and the SOTW observation interface connect to two electrically decoupled pairs of conductors. One illustration of this observation mode is when the pulse interface is imbedded in the breaker box in a pair of substitute circuit breakers, which may isolate the circuits from the common bus bars. The first substitute circuit breaker inserts pulses into the two conductors of the first circuit causing the impedance discontinuities associated with that circuit to radiate. Radiation is received due to impedance discontinuities associated with the second circuit. Received pulses then propagate along the second circuit to be observed at the second substitute circuit breaker. Often, the impedance discontinuities of the first circuit are not collocated with impedance discontinuities of the second circuit resulting in the lack of mono-static mode observations. The result is a system of spatially separated sequential impulse radar sources on the first circuit and a system of spatially separated sequential radar receivers on the second circuit with the bi-static sensing region surrounding the free space coupling of the two systems. The exact configuration depends on the circuit configurations within the facility and the choice of circuits.

An additional illustration of the pseudo bi-static SOTW observation mode can use two outlet pulse interfaces on two electrically decoupled circuits. Often, circuits within a single structure are coupled at least through the bus bars in the breaker box. A desired configuration using outlet interfaces on two separate circuits may require additionally isolating at least one of the circuits from the bus bars.

In many structures in the United States it is possible to create two isolated systems (one radiating and one receiving) within the same electrical network from outside the structure. For example, as FIG. 4 shows, a three conductor main feeder cable wired to the breaker box bus bars in such a way that the Hot A conductor is coupled to one bus bar while the Hot B conductor is coupled to the other bus bar. This creates two pairs of conductors (1) Hot A and Neutral and (2) Hot B and Neutral, where the Neutral is shared with both pairs. In such an arrangement as illustrated in FIG. 4, an insert interface can be connected at the main power feeder cable to Bus A and neutral to use Bus A as a radiation system and an observation interface can be connected at the main power feeder cable to Bus B and neutral to use Bus B as the receiving system.

The above-described processes can be implemented in digital electronic circuitry, or in computer hardware, firmware, software, or in combinations of them. The implementation can be as a computer program product, i.e., a computer program tangibly embodied in an information carrier, e.g., in a machine-readable storage device or in a propagated signal, for execution by, or to control the operation of, data processing apparatus, e.g., a programmable processor, a computer, or multiple computers. A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a communication network.

Method steps can be performed by one or more programmable processors executing a computer program to perform functions of the invention by operating on input data and generating output. Method steps can also be performed by, and apparatus can be implemented as, special purpose logic circuitry, e.g., an FPGA (field programmable gate array) or an ASIC (application-specific integrated circuit). Modules can refer to portions of the computer program and/or the processor/special circuitry that implements that functionality.

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. Data transmission and instructions can also occur over a communications network. Information carriers suitable for embodying computer program instructions and data include all forms of non-volatile memory, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in special purpose logic circuitry.

To provide for interaction with a user, the above described processes can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer (e.g., interact with a user interface element). A touch screen can also be used to serve as the dual purpose of display and input. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The invention has been described in terms of particular embodiments. The alternatives described herein are examples for illustration only and not to limit the alternatives in any way. The steps of the invention can be performed in a different order and still achieve desirable results. Other embodiments are within the scope of the following claims.

What is claimed is:

1. A method for topological mapping using conductive infrastructure, the method comprising:
exciting at least a portion of a conductive infrastructure of a structure with an excitation signal;
receiving a radiated signal, the radiated signal being based on the excitation signal and an impedance discontinuity within the conductive infrastructure; and
determining a location associated with the impedance discontinuity based on the received radiated signal.

2. The method of claim 1, wherein receiving comprises receiving the radiated signal using the conductive infrastructure.

3. The method of claim 2, wherein receiving comprises receiving the radiated signal using the impedance discontinuity within the conductive infrastructure.

4. The method of claim 1, wherein receiving comprises receiving the radiated signal using an antenna.

5. The method of claim 1, wherein receiving comprises receiving the radiated signal after the radiated signal has been reflected off an element of a non-electrical infrastructure.

6. The method of claim 1, wherein receiving comprises receiving the radiated signal using a first conductor of the conductive infrastructure that is electrically insulated from a second conductor of the conductive infrastructure through which the excitation signal is carried.

7. The method of claim 1, further comprising receiving a reflected signal, the reflected signal being based on the excitation signal and the impedance discontinuity within the conductive infrastructure,
wherein determining comprises determining the location associated with the impedance discontinuity based on the received radiated signal and the received reflected signal.

8. The method of claim 7, wherein receiving the reflected signal comprises receiving the reflected signal using the conductive infrastructure.

9. The method of claim 7, wherein the reflected signal is not based on a radiated signal received by the impedance discontinuity.

10. The method of claim 7, wherein the reflected signal is based on a radiated signal received by the impedance discontinuity.

11. The method of claim 7, wherein the reflected signal is based on multiple reflections in free space.

12. The method of claim 7, wherein the reflected signal is based on a radiated signal received by the impedance discontinuity that is generated by a different impedance discontinuity.

13. The method of claim 7, wherein the reflected signal is based on a radiated signal received using a first conductor of the conductive infrastructure that is electrically insulated from a second conductor of the conductive infrastructure through which the excitation signal is carried.

14. The method of claim 1, wherein exciting comprises transmitting the excitation signal using a connection to the conductive infrastructure.

15. The method of claim 14, wherein exciting comprises matching the connection with an impedance value associated with the conductive infrastructure.

16. The method of claim 14, wherein the connection comprises a circuit breaker box, a transformer, an outlet, or any combination thereof.

17. The method of claim 1, wherein exciting comprises transmitting the excitation signal using an antenna.

18. The method of claim 1, wherein determining comprises comparing the received reflected and radiated signals to a model.

19. The method of claim 18, wherein determining comprises iteratively changing a parameter of the model.

20. The method of claim 18, wherein the model includes propagation velocities, radiation efficiencies, refractions, attenuation parameters, or any combination thereof.

21. The method of claim 18, wherein determining comprises determining the location when the received reflected and radiated signals match the model.

22. The method of claim 21, wherein determining when the received reflected and radiated signals match the model comprises determining to a probabilistically high confidence level that there is a match.

23. The method of claim 1, wherein the received and reflected signals are based on a plurality of impedance discontinuities and determining comprises determining locations associated with the plurality of impedance discontinuities.

24. The method of claim 23, further comprising determining a layout of the structure based on the locations.

25. The method of claim 24, wherein determining the layout further comprises displaying at least a portion of the layout of the structure.

26. The method of claim 24, wherein determining the layout further comprises determining coordinates.

27. The method of claim 24, wherein determining the layout further comprises determining a corresponding probability each of the locations.

28. The method of claim 1, wherein the conductive infrastructure comprises electrical power wiring.

29. The method of claim 1, wherein the conductive infrastructure comprises at least two conductors.

30. The method of claim 1, wherein the conductive infrastructure comprises non-metallic sheathed cable.

31. The method of claim 1, wherein the excitation signal comprises a radar signal.

32. The method of claim 1, wherein the excitation signal comprises a broadband signal.

33. The method of claim 1, wherein the location comprises a spatial location.

34. The method of claim 1, wherein the location comprises a multi-dimensional location.

35. A system for topological mapping using conductive infrastructure, the system comprising:
a signal generator adapted to excite at least a portion of a conductive infrastructure of a structure with an excitation signal; and
a signal processor adapted to
i) receive a radiated signal and a reflected signal, the radiated and the reflected signals being based on the excitation signal and an impedance discontinuity within the conductive infrastructure, and
ii) determine a location associated with the impedance discontinuity based on the received radiated and reflected signals.

36. A computer program product, tangibly embodied in an information carrier, for topological mapping using conductive infrastructure, the computer program product including instructions being operable to cause data processing apparatus to:
excite at least a portion of a conductive infrastructure of a structure with an excitation signal;
receive a radiated signal and a reflected signal, the radiated and the reflected signals being based on the excitation signal and an impedance discontinuity within the conductive infrastructure; and
determine a location associated with the impedance discontinuity based on the received radiated and reflected signals.
